(19) United States
(12) Patent Application Publication
(10) Pub. No.: US 2025/0089245 A1
(43) Pub. Date: Mar. 13, 2025

(54) SEMICONDUCTOR STRUCTURE AND METHODS FOR FORMING THE SAME

(71) Applicant: WINBOND ELECTRONICS CORP., Taichung City (TW)

(72) Inventors: Cheng-Shuai LI, Taichung City (TW); Meng-Hsien TSAI, Taichung City (TW); Yueh-Feng LU, Taichung City (TW); Kao-Tsair TSAI, Taichung City (TW)

(21) Appl. No.: 18/500,586

(22) Filed: Nov. 2, 2023

(30) Foreign Application Priority Data
Sep. 11, 2023 (TW) 112134496

(51) Int. Cl. H10B 41/20; H10B 41/10; H10B 43/10; H10B 43/20

(52) U.S. Cl. CPC H10B 41/20; H10B 41/10; H10B 43/10; H10B 43/20

(57) ABSTRACT

A semiconductor structure includes a substrate and a word line. The substrate includes active regions and non-active regions that are alternately disposed in the first direction and extend in the second direction. The word line across the active regions and the non-active regions. The word line includes first conductive portions corresponding to the active regions, isolation pillars corresponding to the non-active regions, an inter-gate dielectric layer disposed on the first conductive portions and the isolation pillars, and a second conductive portion disposed on the inter-gate dielectric layer and extends in the first direction. The first conductive portions and the isolation pillars are disposed alternately in the first direction. Protruding parts of the second conductive portion correspond to the non-active regions, and the isolation pillars are on opposite sides of the corresponding protruding parts in a cross-section of the non-active region along the second direction.

### CROSS REFERENCE TO RELATED APPLICATIONS

This application claims priority of Taiwan Patent Application No. 112134496, filed on Sep. 11, 2023, the entirety of which is incorporated by reference herein.

### BACKGROUND

### Technical Field

The disclosure relates to a semiconductor structure and methods for forming the same, and it relates to a semiconductor structure that can reduce parasitic capacitance and improve electrical performance and the methods for forming the same.

### Description of the Related Art

Currently, the semiconductor manufacturing is developing towards the miniaturization of components. This is accompanied by many challenges. For example, in the process of manufacturing flash memory, in order to separate the stacked structures from each other to form word lines, a patterning process is required. However, if the material layer that is to be etched has a height discrepancy, an over-etching process is required to completely remove said material layer. This over-etching process leads to lateral etching, which can have an undesired effect on the sidewalls of the stacked structure, thereby damaging the profile of the stacked structure.

### SUMMARY

Some embodiments of the present disclosure provide a semiconductor structure that includes a substrate and a word line over the substrate. The substrate has active regions and non-active regions. The active regions and the non-active regions are alternately disposed in the first direction and extend in the second direction. The word line across the active regions and the non-active regions. The word line includes: first conductive portions over the corresponding active regions; isolation pillars over the corresponding non-active regions, wherein the first conductive portions and the isolation pillars are disposed alternately in the first direction; an inter-gate dielectric layer on the first conductive portions and the isolation pillars; and a second conductive portion on the inter-gate dielectric layer and extending in the first direction, wherein protruding parts of the second conductive portion are positioned over the corresponding non-active regions. The isolation pillars are formed on opposite sides of the corresponding protruding parts in a cross section of the non-active regions along the second direction.

Some embodiments of the present disclosure provide a method for forming a semiconductor structure. The method includes providing a substrate that has active regions and non-active regions, wherein the active regions and the non-active regions are alternately disposed in a first direction and extend in a second direction; and forming a word line over the substrate and across the active regions and the non-active regions. The word line includes first conductive portions over the corresponding active regions; isolation pillars over the respective non-active regions, wherein the first conductive portions and the isolation pillars are disposed alternately in the first direction; an inter-gate dielectric layer on the first conductive portions and the isolation pillars; and a second conductive portion on the inter-gate dielectric layer and extending in the first direction, wherein protruding parts of the second conductive portion are positioned over the corresponding active regions, and the isolation pillars are formed on opposite sides of the corresponding protruding parts in a cross section of the non-active regions along the second direction.

### BRIEF DESCRIPTION OF THE DRAWINGS

FIG. 1, FIG. 2, FIG. 3, FIG. 4, FIG. 4A, FIG. 4B, FIG. 5, FIG. 5A, FIG. 5B, FIG. 6, FIG. 6A and FIG. 6B illustrate cross-sectional views of intermediate stages of a semiconductor structure manufacturing in accordance with some embodiments of the present disclosure.

FIG. 2A and FIG. 2B are top views of parts of a memory cell region of a semiconductor structure in accordance with some embodiments of the present disclosure.

FIG. 7 is a top view of an intermediate stage of a semiconductor structure manufacturing in accordance with some embodiments of the present disclosure.

FIG. 8A is a schematic diagram of an intermediate stage of manufacturing of word lines formed by a conventional method.

FIG. 8B is a cross-sectional view taken along line 8B-8B of the structure in FIG. 8A.

FIG. 9A is a schematic diagram of an intermediate stage of manufacturing of word lines formed by the method in accordance with some embodiments of the present disclosure.

FIG. 9B is a cross-sectional view taken along line 9B-9B of the structure in FIG. 9A.

### DETAILED DESCRIPTION

The semiconductor structure and method for forming the same in accordance with the embodiments of the present disclosure can be applied to non-volatile memory, such as flash memory. However, the present disclosure is not limited thereto.

Referring to FIG. 1, a substrate 10 is provided. The substrate 10 has trenches that are recessed from the top surface 10a of the substrate 10. Next, a tunnel dielectric layer 11 is formed to cover the substrate 10 and conformally deposited at the sidewalls and the bottom surfaces of the trenches. The substrate 10 includes non-active regions A2 and active regions A1 that are separated by the trenches. The active regions A1 and the non-active regions A2 are alternately arranged in the first direction D1 (e.g., X direction) and extend in the second direction D2 (e.g., Y direction). The second direction D2 and the first direction D1 may be perpendicular to each other.

First conductive materials 12 are formed on the tunnel dielectric layer 11 and positioned at the active regions A1. Isolation materials 14 are formed in the trenches and positioned at the non-active region A2. The first conductive materials 12 and the isolation materials 14 extend in the second direction D2 and are arranged alternately in the first direction D1. The top surfaces 14a of the isolation materials 14 may be coplanar with the top surfaces 12a of the first conductive materials 12.

The substrate 10 may include silicon, gallium arsenide, gallium nitride, silicon germanium, silicon on insulator (SOI), another suitable material, or a combination of the foregoing materials. The tunnel dielectric layer 11 includes, for example, oxide or a high dielectric constant material.

The first conductive material 12 may include polysilicon, another suitable conductive material, or a combination of the foregoing materials. In the application of non-volatile memory structures, the first conductive material 12 can be patterned in subsequent process to form a bottom gate (such as floating gate) of each of the functional bits. The first conductive material 12 may be formed by a deposition process and a patterning process. In addition, a dielectric material is formed over the substrate 10 and fills the aforementioned trenches. The dielectric material may include oxides, such as silicon oxide. The isolation material 14 may be a single-layer structure or multi-layer structure. In one example, the isolation material 14 includes an oxide liner and a dielectric fill layer.

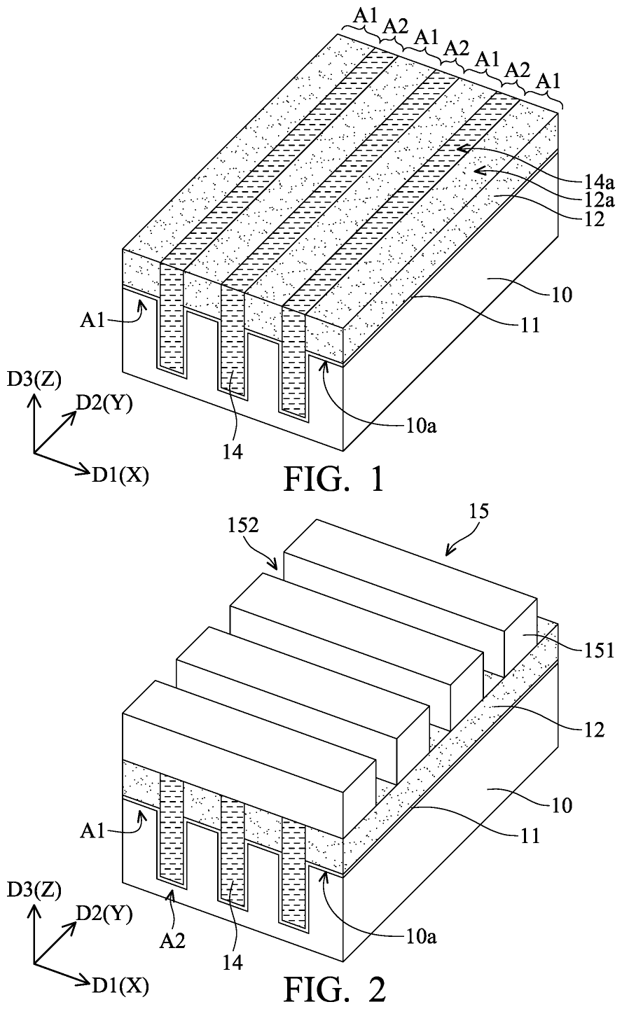

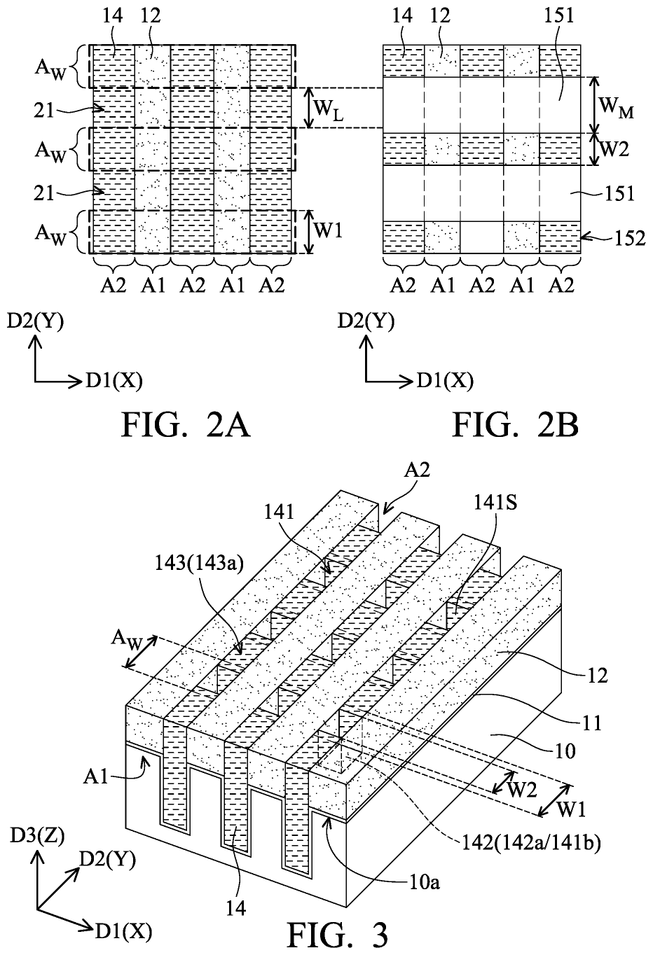

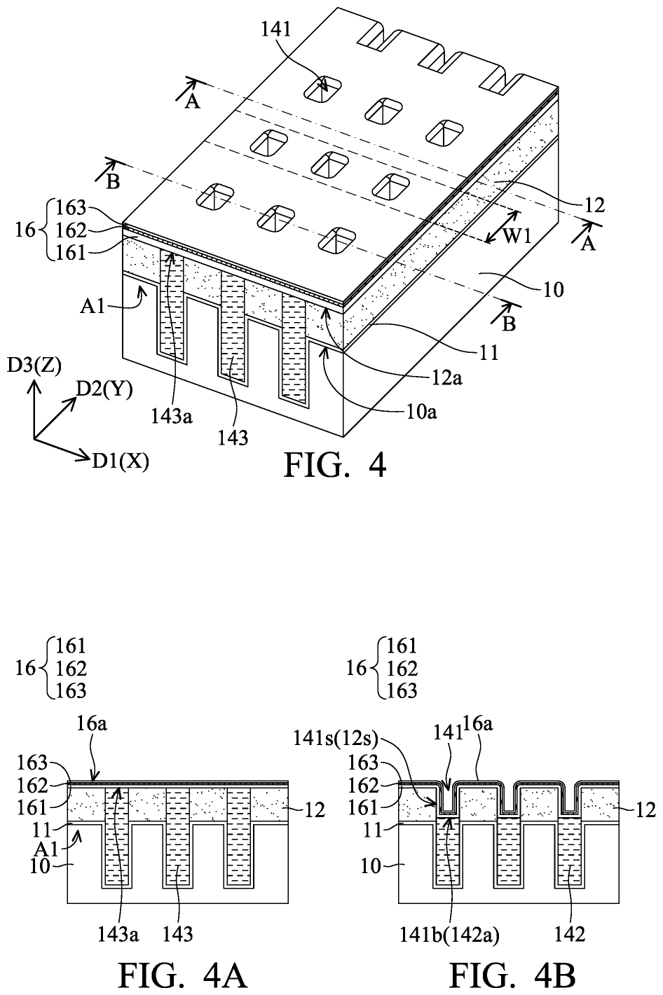

Referring to FIG. 2, a mask 15 is provided over the substrate 10. The mask 15 is, for example, a patterned photoresist. The mask 15 includes strip patterns 151 that are separated by gaps 152. Specifically, the strip patterns 151 extend in the first direction D1 and spans to cover parts of the isolation material 14 and parts of the first conductive material 12. The gaps 152 expose other parts of the isolation material 14 and other parts of the first conductive material 12.

FIG. 2A and FIG. 2B are top views of parts of a memory cell region of a semiconductor structure in accordance with some embodiments of the present disclosure. The memory cell region includes word line regions A_{W} that extend in the first direction D1, and active regions A1 that extend in the second direction D2. Word lines (such as the word lines 20 shown in FIG. 6) formed subsequently are positioned in the word line regions A_{W} and are separated from each other.

The word line region A_{W}, the gap 21 between the word line regions A_{W}, the stripe pattern 151, and the gap 152 between the stripe patterns 151 have widths W1, W_{L}, W_{M} and W2 in the second direction D2, respectively. The strip patterns 151 may be provided corresponding to the gaps 21 between two adjacent word line regions A_{W}, and each of the strip patterns 151 at least partially overlaps the word line regions A_{W} that are on both sides of the strip pattern 151.

In this exemplified embodiment, the width W_{M} of the stripe pattern 151 is greater than the width W_{L} of the gap 21 that is between adjacent word line regions A_{W}. In addition, the width W1 of the word line region A_{W} is greater than the width W2 of the gap 152 that is between adjacent stripe patterns 151.

After the mask 15 is formed above the substrate 10, the portions of the isolation material 14 that are not covered by the stripe patterns 151 are removed, in accordance with some embodiments of the present disclosure. Thus, the isolation material 14 is recessed to form recesses 141, as shown in FIG. 3. In some embodiments, the bottoms of the recesses 141 are level with the top surface 10a of the substrate 10 or slightly above the top surface 10a of the substrate 10.

The exposed portions of the isolation material 14 can be removed by an etching process according to a suitable ratio of etching selectivity of the isolation material 14 to the first conductive material 12.

Afterwards, the mask 15 is removed, for example, by an ashing process.

The remaining portions of the isolation material 14 include the recessed isolation structures 142 and isolation islands 143 that are protruded from the isolation structures 142. The isolation islands 143 are separated from each other by the recesses 141 in the second direction D2, and separated by the first conductive material 12 in the first direction D1. In other words, the isolation islands 143 and the recesses 141 are alternately formed in the non-active regions A2.

In this exemplified embodiment, the width W2 of the gap 152 can be referred to as the width W2 (in the second direction D2) of the recess 141.

It should be noted that unlike the conventional process in which the entire isolation material 14 is recessed, the isolation material 14 is partially recessed in the process of the embodiment to form the recesses 141 and the isolation islands 143.

FIG. 4A and FIG. 4B are cross-sectional views taken along line A-A and line B-B of the structure in FIG. 4, respectively. Line A-A corresponds to the positions of the isolation islands 143, and line B-B corresponds to the positions of the recesses 141. Referring to FIG. 4A and FIG. 4B, the inter-gate dielectric material 16 is formed to cover the top surfaces 143a of the isolation islands 143 and the top surfaces 12a of the first conductive materials 12. In addition, the inter-gate dielectric material 16 is conformably deposited on the sidewalls 141s and the bottom surfaces 141b of the recesses 141. The bottom surfaces 141b of the recesses 141 are also referred to as the top surfaces 142a of the recessed isolation structures 142.

Although each of the parts of the inter-gate dielectric material 16 that is conformally deposited in the recess 141 presents an undulating surface, other parts of the inter-gate dielectric material 16 that are formed on the isolation islands 143 have flat surfaces since they are supported by the top surfaces 143a of the isolation islands 143 and the top surfaces 12a of the first conductive materials 12.

The inter-gate dielectric material 16 may be a multi-layer structure, and may include oxide, nitride, or a combination of the foregoing materials. In one embodiment, the inter-gate dielectric material 16 includes a first oxide layer 161, a nitride layer 162 and a second oxide layer 163 from bottom to top. For example, the inter-gate dielectric material 16 includes silicon oxide, silicon nitride and silicon oxide from bottom to top. However, the disclosure is not limited thereto. The inter-gate dielectric material 16 may be a single-layer structure, or a multi-layer structure that has more dielectric layers or more complex structure.

In some embodiments, the inter-gate dielectric material 16 may be formed by a physical vapor deposition, a chemical vapor deposition, an atomic layer deposition, another suitable process, or a combination of the foregoing processes.

FIG. 5A and FIG. 5B are cross-sectional views taken along line A-A and line B-B of the structure in FIG. 5, respectively. Line A-A corresponds to the positions of the isolation islands 143, and line B-B corresponds to the positions of the recesses 141. Referring to FIG. FIG. 5A and FIG. 5B, a second conductive layer 18 is formed on the inter-gate dielectric material 16 to fill the remaining spaces beyond the inter-gate dielectric material 16 in the recesses 141.

Specifically, the second conductive layer 18 includes a main body layer 181 and multiple protruding parts 182. The main body layer 181 is formed over the isolation islands 143 and the first conductive materials 12. The main body layer 181 has the top surface 181a and the bottom surface 181b. The protruding parts 182 are positioned under the bottom surface 181b of the main body layer 181 and protrude from the bottom surface 181b toward the substrate 10. The lower surfaces 182b of the protruding parts 182 face away from the main body layer 181. In addition, the protruding parts 182 are located in the remaining spaces beyond the inter-gate dielectric materials 16 in the recesses 141. Therefore, the sidewalls and the lower surfaces 182b of the protruding parts 182 are surrounded and covered by the inter-gate dielectric material 16. In some exemplified embodiments, the protruding parts 182 correspond to the non-active regions A2. According to the separated positions of the recesses 141, the protruding parts 182 are separated from each other.

The second conductive layer 18 may be a single-layer structure or a multi-layer structure, and may include polysilicon, metal, metal silicide, another conductive material, or a combination of the foregoing materials. In this exemplified embodiment, the second conductive layer 18 includes polysilicon.

The second conductive layer 18 may be formed by a deposition process, for example, a physical vapor deposition process, a chemical vapor deposition process, an atomic layer deposition process, another suitable process, or a combination of the foregoing processes.

Referring to FIG. 6, a patterning process is performed on the second conductive layer 18, the inter-gate dielectric material 16, the isolation islands 143 and the first conductive materials 12 to form word lines 20 above the substrate 10. The word lines 20 are separated from each other in the second direction D2 and extend in the first direction D1. In addition, the word lines 20 cross over the alternating active regions A1 and non-active regions A2.

Each of the word lines 20 includes multiple first conductive portions 120 that are positioned on the corresponding active regions A1, and multiple isolation pillars 143P that are positioned on the corresponding non-active regions A2. The isolation pillars 143P are the remaining portions of the isolation islands 143 after the patterning process is performed. In some embodiments, the word line 20 further includes an inter-gate dielectric layer 160 and a second conductive portion 180. The inter-gate dielectric layer 160 covers the top surfaces 120a of the first conductive portions 120 and the top surfaces 143P-a of the isolation pillars 143P. The second conductive portion 180 is formed on the inter-gate dielectric layer 160. It should be noted that the first conductive portions 120 and the isolation pillars 143P are alternately arranged in the first direction D1.

In the application of flash memory, the first conductive portion 120 and the second conductive portion 180 can be used as a floating gate and a control gate, respectively.

According to some embodiments, the word lines 20 can be formed by a deposition process, a lithographic patterning process and an etching process. For example, a hard mask material (not shown) may be formed on second conductive layer 18. Then, a patterned photoresist corresponding to the positions of the word lines 20 is formed on the hard mask material, and the hard mask material is etched according to the patterned photoresist to form a hard mask. Then, the patterned photoresist is removed and the underlying material layers and components are etched according to the hard mask. In some embodiments, the etching process may include a dry etching process, a wet etching process, a plasma etching process, a reactive ion etching process, another suitable process, or a combination of the foregoing processes.

FIG. 6A and FIG. 6B show three-dimensional schematic views taken along line 1-1 corresponding to the active region A1 and line 2-2 corresponding to the non-active region A2 in FIG. 6, respectively. FIG. 6A shows a cross-section of the first conductive portion 120, the inter-gate dielectric layer 160 and the second conductive portion 180 in the active region A1. FIG. 6B shows a cross-section of the second conductive portion 180, the inter-gate dielectric layer 160 and the isolation pillar 143P in the non-active region A2.

Refer to FIG. 6, FIG. 6A and FIG. 6B. Viewed from the second direction D2, the top surfaces 120a of the first conductive portions 120 and the top surfaces 143P-a of the isolation pillars 143P are coplanar. Therefore, the inter-gate dielectric layer 160 extends at the same horizontal level.

Each of the isolation pillars 143P has two opposite sidewalls 143P-s, and the two sidewalls 143P-s respectively contact the inner sidewalls 120-1i and 120-2i of two adjacent first conductive portions.

In addition, the outer sidewalls 120s of the first conductive portions 120 and the outer sidewalls 143P-o of the isolation pillars 143P are coplanar.

As shown in FIG. 6 and FIG. 6A, in each of the active regions A1, an overall stack of the word line 20 has a complete and well-configured profile. The first conductive portion 120 has a sufficient and complete overlapping area with the active region A1 below and also has a sufficient and complete overlapping area with the second conductive portion 180 above. Therefore, the subsequently formed semiconductor structure has good electrical performance, such as better word line coupling ratio and more stable erase threshold voltage.

As shown in FIG. 6 and FIG. 6B, the cross-section of the word line 20 in the non-active region A2 shows a dielectric structure with a U-shaped cross section in the recess 141. The dielectric structure includes an inter-gate dielectric layer 160 with a U-shaped cross section (which can be regarded as the first dielectric structure) and an isolation component with a U-shaped cross section (that includes an isolation pillar 143P and a recessed isolation structure 142, which can be collectively referred to as the second dielectric structure). Details of the dielectric structure will be described later.

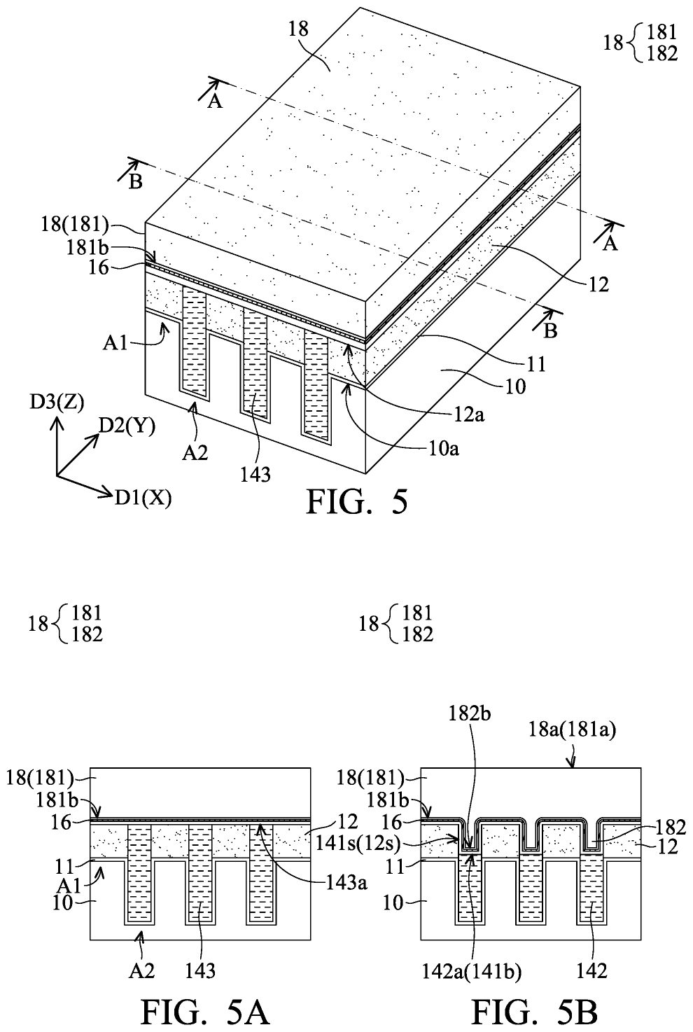

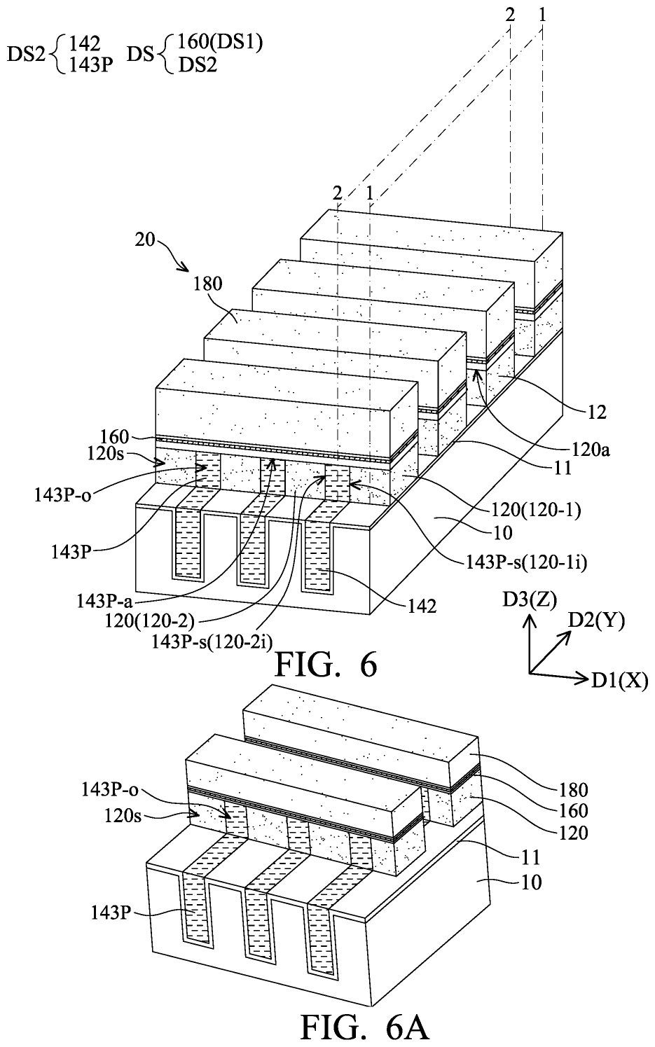

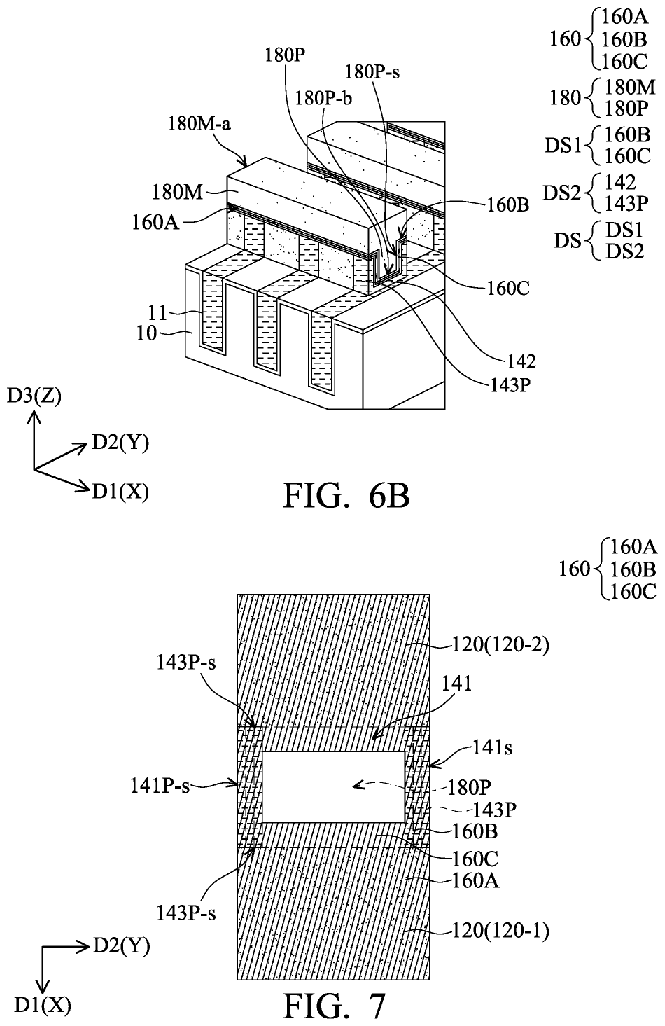

Refer to FIG. 3, FIG. 4, FIG. 6B and FIG. 7. FIG. 7 is a top view showing a cross-section of a structure after the inter-gate dielectric layer 160 is formed. Specifically, FIG. 7 shows a recess 141, two of the first conductive portions 120-1 and 120-2, and two opposite isolation pillars 143P. The two opposite isolation pillars 143P connect the two adjacent first conductive portions 120-1 and 120-2, respectively. Refer to FIG. 7, the inter-gate dielectric layer 160 that is on the first conductive portions 120 and the isolation pillars 143P is also deposited along the sidewalls of the recess 141 and covers the bottom surface (not shown) of the recess 141. The inter-gate dielectric layer 160 on the recess 141 presents a ring-shaped cross-section, and the protruding part 180P that subsequently fills the recess 141 is surrounded by the inter-gate dielectric layer 160.

According to some embodiments, the word line 20 has a recess 141 in the non-active region A2, and the inter-gate dielectric layer 160 is conformally deposited at the recess 141 and positioned within the word line region. The recess 141 is defined by the inner sidewalls 120-1i and 120-2i of the adjacent first conductive portions 12 and the two opposite isolation pillars 143P. Therefore, the inter-gate dielectric layer 160 covers the top surfaces 143P-a and the inner sidewalls (not shown) of the isolation pillars 143P, and covers the top surfaces 12a and the inner sidewalls 120-1i and 120-2i of the first conductive portions 12.

As shown in FIG. 6, FIG. 6B and FIG. 7, after the word lines 20 are formed, the inter-gate dielectric layer 160 includes first parts 160A positioned on the top surfaces 12a of the first conductive portions 12, second parts 160B positioned on the top surfaces 143P-a of the isolation pillars 143P and third parts 160C formed in the recesses 141.

Specifically, the first parts 160A and the second parts are alternately arranged in the extending direction of the word lines 20. Since the top surfaces 143P-a of the isolation pillars 143P are substantially coplanar with the top surfaces 12a of the first conductive portions 12, the first parts 160A are substantially coplanar with the second parts 160B.

As shown in FIG. 6B, the lower portion (i.e., the protruding part 180P described later) of the second conductive portion 180 in the non-active region A2 is surrounded by the dielectric stack DS. The dielectric stack DS has a U-shaped cross section in the cross section along the second direction D2. Specifically, the dielectric stack DS includes a first dielectric structure DS1 and a second dielectric structure DS2. The first dielectric structure DS1 includes the second parts 160B and the third parts 160C of the inter-gate dielectric layer 160. The first dielectric structure DS1 has a U-shaped cross section in the cross-section along the second direction D2 (FIG. 6B), and also has a U-shaped cross section in the cross-section along the first direction D1 (FIG. 5B). In addition, the third part 160C in the recesses in the non-active regions A2 also has a U-shaped cross section in the cross-section along the second direction D2. The second dielectric structure DS2 includes the isolation pillars 143P and the recessed isolation structures 142 that are connected to the isolation pillars 143P. In addition, the second dielectric structure DS2 has a U-shaped cross section along the second direction D2.

According to some embodiments, the isolation pillars 143P and the recessed isolation structures 142 form an integrated piece. Referring to FIG. 6B and FIG. 7, it should be noted that the cross-section of the second dielectric structure DS2 in the extending direction of the word lines 20 does not have a U-shaped cross section 20 since the isolation pillars 143P do not cover the inner sidewalls of the first conductive portions 120 that are perpendicular to the extension direction of the word lines 20.

Referring to FIG. 6B, the second conductive portion 180 of the word line 20 includes a main body 180M and protruding parts 180P. The main body 180M is formed above the isolation pillars 143P and the first conductive materials 12. The protruding parts 180P are positioned underlying the bottom surface of the main body 180M and protrude from the bottom surface toward the substrate 10. The lower surfaces 180P-b of the protruding parts 180P face away from the main body 180M.

The protruding parts 180P are formed in the remaining spaces beyond the inter-gate dielectric layer 160 in the recesses 141. Thus, all of the sidewalls 180P-s and the lower surfaces 180P-b of the protruding parts 180P are surrounded and covered by the inter-gate dielectric layer 160. The protruding parts 180P are located in the corresponding non-active regions A2 and are spaced apart from each other in the extending direction of the word lines 20.

Referring to FIG. 6A and FIG. 6B, in the cross-section along the second direction D2, the second conductive portion 180 corresponding to the active regions A1 has a rectangular cross section, and the second conductive portion 180 corresponding to the non-active regions A2 (including the main body 180M and the protruding parts 180P) has a T-shaped cross section. Therefore, the second conductive portion 180 includes alternating rectangular structures and T-shaped structures in the first direction D1.

After the word lines are formed, additional components may be formed to fabricate the semiconductor structure.

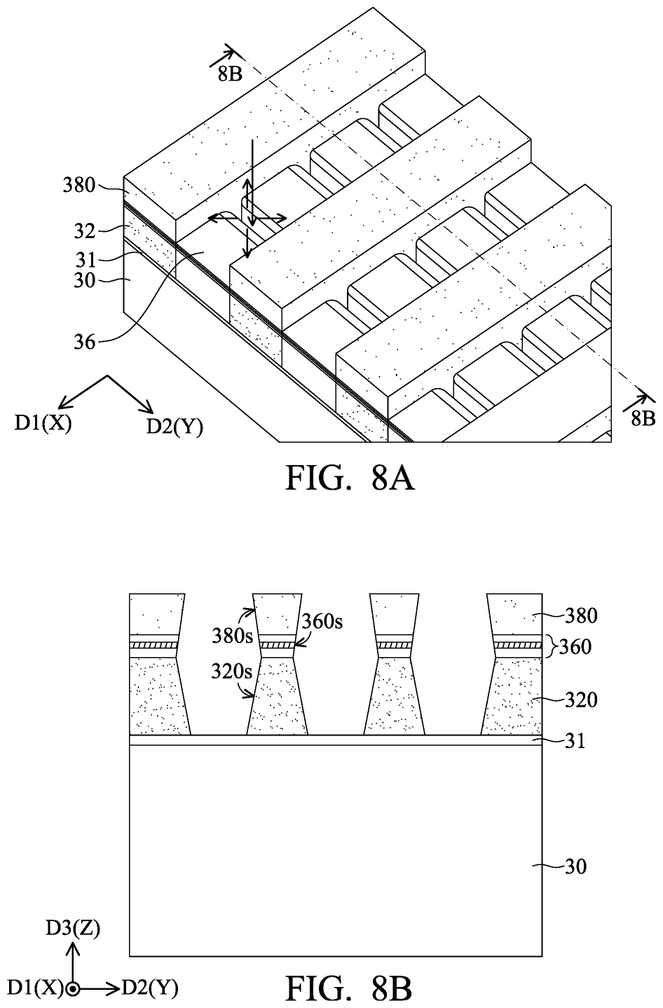

FIG. 8A is a schematic diagram of an intermediate stage of manufacturing of word lines formed by a conventional method. FIG. 8B is a cross-sectional view taken along line 8B-8B of the structure in FIG. 8A. The features/components in FIG. 8A and FIG. 8B similar or identical to that in the embodiments as described above are designated with similar or the same reference numbers, and the details of those similar or the identical features/components are not repeated herein.

According to the conventional manufacturing method, after the step of planarizing the first conductive materials 32 and the isolation materials (not shown) in FIG. 8A is performed (similar to the step in FIG. 1), all the isolation materials are recessed to form recessed isolation structures (not shown). Therefore, the inter-gate dielectric material 36 that is deposited on the relatively protruding first conductive materials 32 and the relatively recessed isolation structures will present an undulating surface in the first direction D1. As shown in FIG. 8A, during the word line patterning process, after portions of the second conductive layer are removed to form the second conductive portions 380, the exposed inter-gate dielectric material 36 has an undulating surface. In the subsequent processes, it is required to remove the exposed inter-gate dielectric material 36 and disconnect the bottoms of the first conductive materials 32 that are positioned under the inter-gate dielectric material 36 in order to prevent the bottoms (such as the first conductive portions 320 in FIG. 8B) of the formed word lines from being connected and leading to short circuit. Conventionally, an over-etching process is performed to completely disconnect the inter-gate dielectric material 36 and the first conductive materials 32. However, due to the height difference between the portions of the inter-gate dielectric material 36, the over-etching process will laterally etch more of the sidewalls of adjacent material stacks (such as the indication of arrows in FIG. 8A), thus damaging the resulting configuration of the word lines and affecting the electrical performance of the semiconductor structure.

According to the cross-section shown in FIG. 8B, after the over-etching process is performed, the lateral etching effect is caused by the height difference between the material layers. That is, the sidewalls 380s of the second conductive portions 380, the sidewalls 360s of the inter-gate dielectric layer 360 and the sidewalls 320s of the first conductive portions 320 that are ideally substantially perpendicular to the substrate 10 are recessed inward.

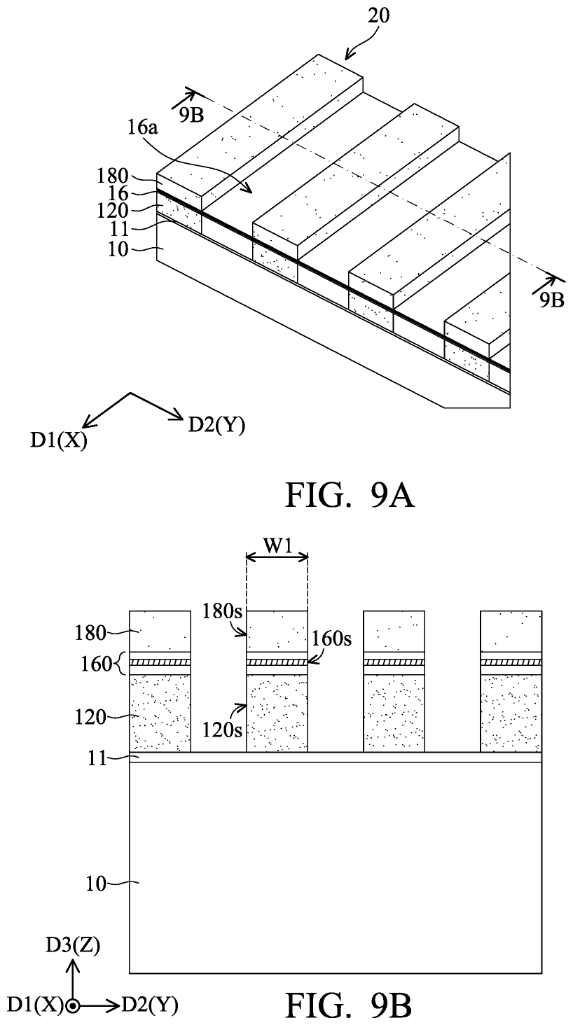

FIG. 9A shows a schematic diagram of an intermediate stage of a method for forming word lines in accordance with some embodiments of the present disclosure. FIG. 9B is a cross-sectional view taken along line 9B-9B of the structure in FIG. 9A.

After the step of planarizing the first conductive materials 12 and the isolation materials 14, the isolation materials 14 are partially recessed to form multiple recesses 141 that are separated from each other. The remaining portions of the isolation materials 14 form multiple isolation islands 143 (FIG. 3). The recesses 141 are formed within the word line regions. Therefore, after the portions of the second conductive layer 18 are removed to form the second conductive portions 180 as shown in FIG. 9A, the exposed inter-gate dielectric material 16 has a flat top surface 16a. In the subsequent process of etching the inter-gate dielectric material 16 and the underlying first conductive materials 12, there is no need to disconnect the bottoms of the first conductive materials 12 by performing an over-etching process, since the material portions to be etched do not have a height difference.

Therefore, after the word lines 20 are formed, as shown in FIG. 9B, the sidewalls 180s of the second conductive portion 180, the sidewalls 160s of the inter-gate dielectric layer 160 and the sidewalls 120s of the first conductive portion 120 are substantially perpendicular to the substrate 10 and coplanar with each other. That is, the aforementioned sidewalls of the second conductive portion 180, the inter-gate dielectric layer 160 and the first conductive portion 120 are not recessed inward. In addition, since there is no lateral etching effect, the undesired defect that the bottom width of the second conductive portion 180 is less than the top width of the second conductive portion 180 does not occur. According to some embodiments, there is a sufficient and complete overlapping area between the first conductive portion 120 of the word line 20 and the underlying active region A1. In addition, there is a sufficient and complete overlapping area between the first conductive portion 120 and the second conductive portion 180 above. Defect of the sidewalls of the second conductive portion 180, the inter-gate dielectric layer 160 and the first conductive portion 120 that are recessed inward does not occur. Thus, the word lines that are fabricated by the method of the embodiments have good profile, so that the semiconductor structure in the application has good electrical performance, such as better word line coupling and more stable erase threshold voltage during operation.

What is claimed is:

1. A semiconductor structure, comprising:
a substrate has active regions and non-active regions, wherein the active regions and the non-active regions are alternately disposed in a first direction and extend in a second direction; and
a word line over the substrate and across the active regions and the non-active regions, wherein the word line comprises:
first conductive portions over the corresponding active regions;
isolation pillars over the corresponding non-active regions, wherein the first conductive portions and the isolation pillars are disposed alternately in the first direction;
an inter-gate dielectric layer on the first conductive portions and the isolation pillars; and
a second conductive portion on the inter-gate dielectric layer and extending in the first direction, wherein protruding parts of the second conductive portion corresponds to the non-active regions, and the isolation pillars are disposed on opposite sides of the corresponding protruding parts in a cross section of the non-active regions along the second direction.

2. The semiconductor structure as claimed in claim 1, wherein top surfaces of the first conductive portions are coplanar with top surfaces of the isolation pillars.

3. The semiconductor structure as claimed in claim 1, wherein the gate dielectric layer covers a top surface and an inner sidewall of each of the isolation pillars, and also covers a top surface and inner sidewalls of each of the first conductive portions.

4. The semiconductor structure as claimed in claim 3, wherein each of the isolation pillars comprises two opposite sidewalls that are in direct contact with the corresponding inner sidewalls of two adjacent first conductive portions.

5. The semiconductor structure as claimed in claim 1, wherein the inter-gate dielectric layer comprises:
first parts, positioned on top surfaces of the first conductive portions; and
second parts, positioned on top surfaces of the isolation pillars,
wherein the first parts and the second parts are positioned at the same horizontal level.

6. The semiconductor structure as claimed in claim 5, wherein the word line has recesses over the corresponding non-active regions, and the inter-gate dielectric layer further comprises:
third parts, disposed on sidewalls and bottom surfaces of the recesses.

7. The semiconductor structure as claimed in claim 1, wherein the second conductive portion comprises:
a main body, extending in the first direction; and
the protruding parts, corresponding to the non-active regions and joined to a bottom surface of the main body, wherein the protruding parts protrude toward the substrate, and lower surfaces of the protruding parts face away from the main body.

8. The semiconductor structure as claimed in claim 7, further comprising:
a dielectric stack surrounding sidewalls and the bottom surfaces of the protruding parts, wherein the dielectric stack includes the isolation pillars and the inter-gate dielectric layer,
wherein in a cross-section of the word line along the second direction, the dielectric stack has a U-shaped cross section that corresponds to each of the non-active regions.

9. The semiconductor structure as claimed in claim 1, wherein the second conductive portion includes portions corresponding to the non-active regions, and the portions have a T-shaped cross-section in the second direction.

10. The semiconductor structure as claimed in claim 1, wherein the second conductive portion includes portions corresponding to the active regions, and the portions have a rectangle-shaped cross-section in the second direction.

11. The semiconductor structure as claimed in claim 1, wherein the word line has recesses over the corresponding non-active regions, and the recesses are separated from each other in the first direction, wherein the inter-gate dielectric layer is conformally deposited in the recesses, and portions of the second conductive portion fill remaining spaces of the recesses.

12. The semiconductor structure as claimed in claim 11, wherein a width of the respective recesses in the second direction is less than a width of the word line in the second direction.

13. The semiconductor structure as claimed in claim 1, further comprising isolation structures in the non-active regions to define the active regions, wherein the isolation pillars extend from the isolation structures in a direction away from the substrate, and the isolation pillars and the isolation structures include the same material.

14. The semiconductor structure as claimed in claim 13, wherein the isolation pillars that are positioned over one of the non-active regions join corresponding portions of the isolation structure so as to collectively form a structure with a U-shaped cross section.

15. A method for forming a semiconductor structure, comprising:
providing a substrate that has active regions and non-active regions, wherein the active regions and the non-active regions are alternately disposed in a first direction and extend in a second direction; and
forming a word line over the substrate and across the active regions and the non-active regions, wherein the word line comprises:
first conductive portions over the corresponding active regions;
isolation pillars over the corresponding non-active regions, wherein the first conductive portions and the isolation pillars are disposed alternately in the first direction;
an inter-gate dielectric layer on the first conductive portions and the isolation pillars; and
a second conductive portion on the inter-gate dielectric layer and extending in the first direction, wherein protruding parts of the second conductive portion corresponds to the non-active regions, and the isolation pillars are disposed on opposite sides of the corresponding protruding parts in a cross section of the non-active regions along the second direction.

16. The method for forming the semiconductor structure as claimed in claim 15, wherein after the substrate is provided, the method further comprises:
forming isolation materials in the non-active regions and first conductive materials in the active regions, wherein top surfaces of the isolation materials are coplanar with top surfaces of the first conductive materials.

17. The method for forming the semiconductor structure as claimed in claim 16, further comprises:
removing portions of the isolation materials to form recesses, wherein remaining portions of the isolation materials include recessed isolation structures and isolation islands that protrude from the isolation structures,
wherein the isolation islands are separated from each other by the recesses in the second direction, and the isolation islands are separated from each other by the first conductive materials in the first direction.

18. The method for forming the semiconductor structure as claimed in claim 17, wherein removing the portions of the isolation materials comprises:
providing a mask above the substrate, wherein strip patterns of the mask extend in the first direction and correspond to gaps between two adjacent word line regions, and a width of each of the strip patterns in the second direction is greater than a width of each of the gaps in the second direction;
removing the portions of the isolation materials that are not covered by the strip patterns of the mask to form the recesses; and
removing the mask.

19. The method for forming the semiconductor structure as claimed in claim 17, wherein after the isolation islands are formed, the method further comprises:
forming an inter-gate dielectric material on the isolation islands and the first conductive materials, wherein the inter-gate dielectric material is conformally formed on sidewalls and bottom surfaces of the recesses; and
forming a second conductive material on the inter-gate dielectric material.

20. The method for forming the semiconductor structure as claimed in claim 19, wherein after the second conductive material is formed, the method further comprises:
performing a patterning process to form the second conductive portion in a word line region, wherein the second conductive portion extends in the first direction;
removing portions of the inter-gate dielectric material to form the inter-gate dielectric layer; and
removing portions of the isolation islands and portions of the first conductive materials, so that remaining portions of the isolation islands form the isolation pillars, and remaining portions of the first conductive materials form the first conductive portions, thereby forming the word line.
